(19) United States
(12) Patent Application Publication
(10) Pub. No.: US 2026/0148782 A1
(43) Pub. Date: May 28, 2026

(54) SEMICONDUCTOR MEMORY DEVICE

(71) Applicant: SK hynix Inc., Gyeonggi-do (KR)

(72) Inventor: Nam Cheol JEON, Gyeonggi-do (KR)

(21) Appl. No.: 19/403,237

(22) Filed: Nov. 28, 2025

(30) Foreign Application Priority Data
Nov. 28, 2024 (KR) 10-2024-0174065

(51) Int. Cl. G11C 16/34; G11C 16/30; G11C 16/32; G11C 29/52

(52) U.S. Cl. CPC G11C 16/349; G11C 16/30; G11C 16/32; G11C 29/52

(57) ABSTRACT

A semiconductor memory device includes a memory block including at least one programmed page and at least one erased page; and a control circuit configured to generate characteristic information for the memory block. The characteristic information includes information related to reliability of the memory block. The semiconductor memory device also includes a peripheral circuit configured to control an operation of the memory block based on the characteristic information. In another example, a semiconductor memory device includes: a memory block including at least one programmed page and at least one erased page; a control circuit configured to generate a block closed ratio (BCR) indicating a ratio of the at least one programmed page in the memory block to a total number of pages in the memory block; and a peripheral circuit configured to control an operation of the memory block based on the block closed ratio (BCR).

### CROSS-REFERENCE TO RELATED APPLICATION

This patent document claims the priority and benefits of Korean patent application No. 10-2024-0174065, filed on Nov. 28, 2024, the disclosure of which is incorporated herein by reference in its entirety.

### TECHNICAL FIELD

The technology and implementations disclosed in this patent document generally relate to a semiconductor memory device for storing data therein.

### BACKGROUND

A semiconductor memory device may include a plurality of memory cells for storing data therein. In addition, the semiconductor memory device may be classified into a nonvolatile memory device that can maintain stored data even when power supply is interrupted, and a volatile memory device that does not preserve data when power supply is interrupted.

Nonvolatile memory devices may include a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), or a ferroelectric RAM (FRAM), and the like.

### SUMMARY

Various embodiments of the present disclosure relate to a semiconductor memory device having improved reliability.

In accordance with an embodiment of the present disclosure, a semiconductor memory device may include a memory block including at least one programmed page and at least one erased page; and a control circuit configured to generate characteristic information for the memory block. The characteristic information includes information related to reliability of the memory block. The semiconductor memory device may also include a peripheral circuit configured to control an operation of the memory block based on the characteristic information.

In accordance with another embodiment of the present disclosure, a semiconductor memory device may include: a memory block including at least one programmed page and at least one erased page; a control circuit configured to generate a block closed ratio (BCR) indicating a ratio of a number of the at least one programmed page in the memory block to a total number of pages in the memory block; and a peripheral circuit configured to control an operation of the memory block based on the block closed ratio (BCR).

In accordance with another embodiment of the present disclosure, a method for operating a memory device that includes a memory block is provided. The method includes generating characteristic information for the memory block. The memory block includes at least one programmed page and at least one erased page, and the characteristic information includes information related to reliability of the memory block. The method also includes controlling an operation of the memory block based on the characteristic information.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating a memory system in accordance with example embodiments.

FIG. 2 is a block diagram illustrating a memory device shown in FIG. 1 in accordance with example embodiments.

FIG. 3 is a schematic diagram illustrating a memory block shown in FIG. 2 in accordance with example embodiments.

FIG. 4 is a circuit diagram illustrating operations of strings shown in FIG. 3 in accordance with example embodiments.

FIG. 5 is a timing diagram illustrating a read operation of a string circuit shown in FIG. 4 in accordance with example embodiments.

FIG. 6A is a diagram illustrating a method for determining a source voltage (SV) described in FIG. 5 in accordance with example embodiments.

FIG. 6B is a diagram illustrating another method for determining a source voltage (SV) described in FIG. 5 in accordance with example embodiments.

FIG. 7 is a diagram illustrating the result of comparison between threshold voltage distributions of an open block and a closed block in accordance with example embodiments.

FIG. 8 is a schematic diagram illustrating a dummy program operation performed by a memory control circuit shown in FIG. 2 in accordance with example embodiments.

FIG. 9 is a diagram showing changes in fail bits over time in a monitoring target in accordance with example embodiments.

### DETAILED DESCRIPTION

Example embodiments provide implementations and examples of a semiconductor memory device for storing data therein that may be used in configurations to substantially address one or more technical or engineering issues and to mitigate limitations or disadvantages encountered in some other semiconductor memory devices. Some implementations of the present disclosure relate to a semiconductor memory device having improved reliability. In recognition of the issues above, the present disclosure may provide a semiconductor memory device that can solve a reliability problem occurring in open blocks of a memory cell array.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

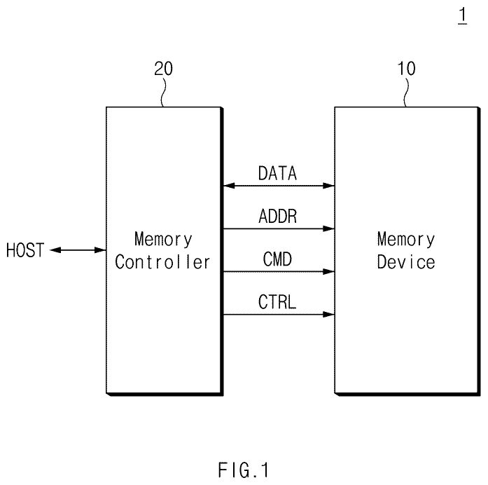

FIG. 1 is a block diagram illustrating an example of a memory system 1 based on some embodiments of the present disclosure.

Referring to FIG. 1, the memory system 1 may include a memory device 10 and a memory controller 20.

The memory system 1 may be implemented as an internal memory embedded in an electronic system (e.g., a smartphone, a tablet, a computer, a TV, etc.). For example, the memory system 1 may be an embedded universal flash storage (UFS), an embedded multimedia card (eMMC), or a solid state drive (SSD). According to one embodiment, the memory system 1 may be implemented as an external memory detachably coupled to an electronic device, and may be, for example, a UFS memory card, a compact flash (CF) card, a secure digital (SD) card, a micro-Secure Digital (micro-SD) card, a mini-Secure Digital (mini-SD) card, an extreme Digital (xD) card, or a memory stick.

The memory system 1 may store data received from a host in the memory device 10 based on an access request from the host, or may read data requested by the host from the memory device 10 and transmit the read data to the host.

The memory device 10 may include a plurality of memory cells, each of which stores data. According to one embodiment, each of the plurality of memory cells may be a nonvolatile memory cell that maintains stored data even when power supply is interrupted. For example, when the memory cell is a nonvolatile memory cell, the memory device 10 may be implemented as an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like. Hereinafter, embodiments of the present disclosure will be described as an example in which the plurality of memory cells is NAND flash memory cells, but the technical idea of the present disclosure is not limited thereto. The memory device 10 may perform program, read, and/or erase operations under control of the memory controller 20.

The memory controller 20 may provide a control signal (CTRL), a command (CMD), and an address (ADDR) to the memory device 10. The control signal (CTRL) may include information necessary for the memory device 10 to perform an operation corresponding to the command (CMD) received from the memory controller 20. For example, the control signal (CTRL) may include information about the sensing parameters necessary for the memory device 10 to read data from memory cells. The command (CMD) may indicate an operation to be performed by the memory device 10 during the program, read, or erase operation. The address (ADDR) may indicate a position at which the memory controller 20 desires to access data in the memory device 10. Data (DATA) may be transmitted and/or received between the memory controller 20 and the memory device 10 based on the command (CMD) and the address (ADDR).

The memory controller 20 may control various operations of the memory device 10 in response to an access request from the host, for example, the program operation for programming data (DATA) in the memory device 10, the read operation for reading data (DATA) from the memory device 10, and/or the erase operation for erasing data (DATA) of the memory device 10. For example, the memory controller 20 may transmit data (DATA) received from the host to the memory device 10 by executing a write command, or may transmit data (DATA) read from the memory device 10 to the host by executing a read command. In addition, the memory controller 20 may provide a clock signal, a chip selection signal, etc. to the memory device 10.

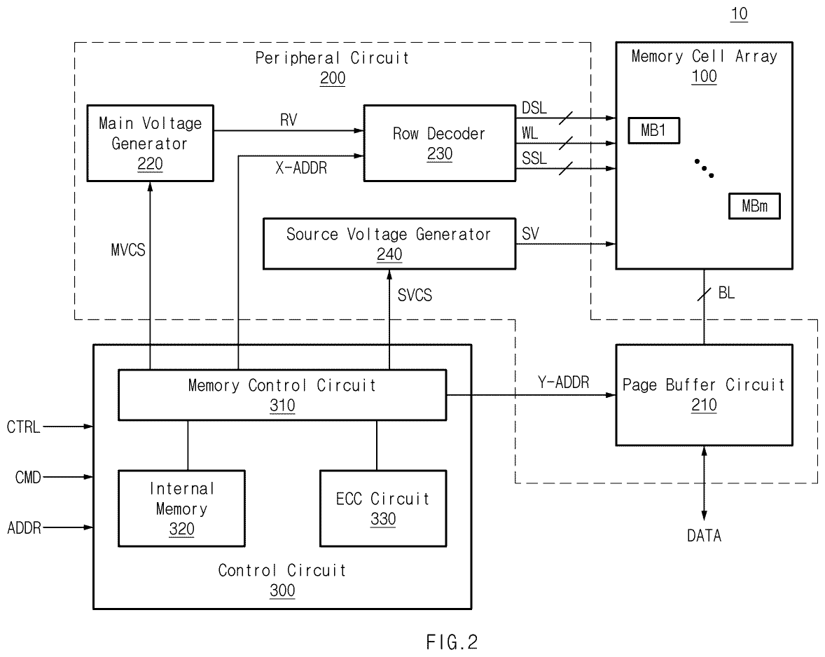

FIG. 2 is a block diagram illustrating an example of the memory device 10 shown in FIG. 1 based on some embodiments of the present disclosure.

Referring to FIG. 2, the memory device 10 may include a memory cell array 100, a peripheral circuit 200, and a control circuit 300. According to one embodiment, the memory device 10 may further include a data input and output (input/output) (I/O) circuit for communication with an external device such as the memory controller 20, or an input/output (I/O) interface for communication with the external device.

The memory cell array 100 may include a plurality of memory cells. The memory cell array 100 may be connected to drain selection lines (DSLs), word lines (WLs), source selection lines (SSLs), and bit lines (BLs). The memory cell array 100 may be connected to a row decoder 230 through the drain selection lines (DSLs), the word lines (WLs), and the source selection lines (SSLs), and may be connected to a page buffer circuit 210 through the bit lines (BLs).

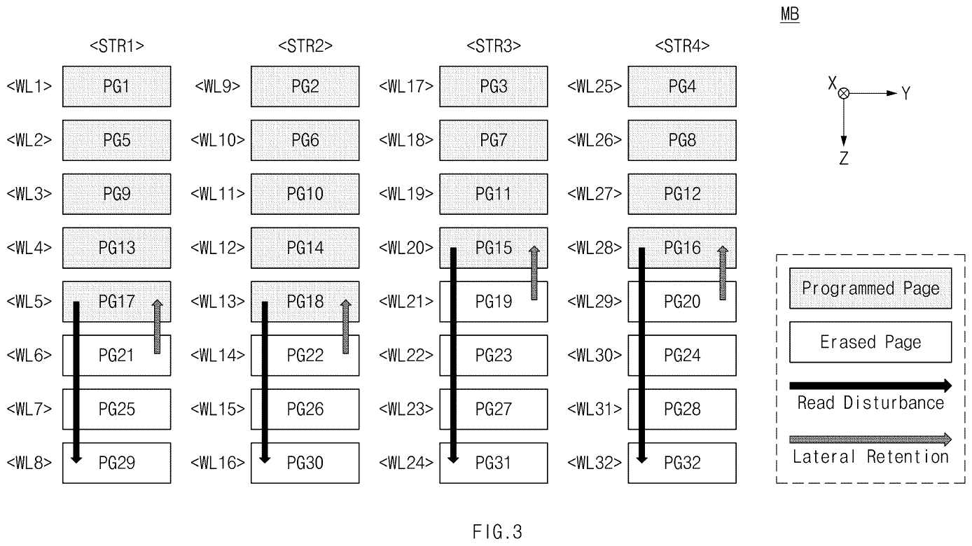

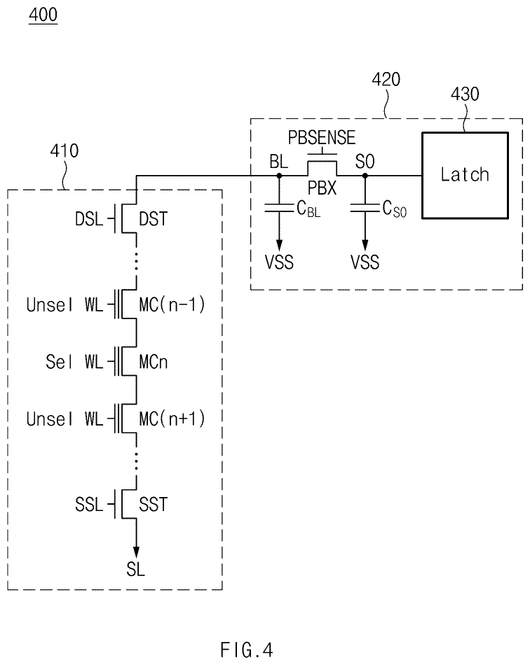

The memory cell array 100 may include a plurality of memory blocks (MB1 to MBm), where ‘m’ is an integer of 2 or greater. Each memory block may include a plurality of memory cells arranged in a two-dimensional (2D) structure or a three-dimensional (3D) structure. According to one embodiment, each memory block (MB1 to MBm) may be or include at least one of a single-level cell (SLC) block including single-level cells (SLCs), a multi-level cell (MLC) block including multi-level cells (MLCs), a triple-level cell (TLC) block including triple-level cells (TLCs), and a quad-level cell (QLC) block including quad-level cells (QLCs). The structure of each memory block (MB1 to MBm) will be described later with reference to FIGS. 3 and 4.

The peripheral circuit 200 may control the operation of the memory cell array 100 under the control of the control circuit 300. The peripheral circuit 200 may include the page buffer circuit 210, a main voltage generator 220, the row decoder 230, and a source voltage generator 240.

The page buffer circuit 210 may operate in response to a control signal of the control circuit 300. The page buffer circuit 210 may select some bit lines among the bit lines (BLs) in response to a column address (Y-ADDR). For example, the page buffer circuit 210 may operate as a write driver or a sense amplifier.

According to one embodiment, during the program operation, the page buffer circuit 210 may operate as a write driver to apply a voltage according to data (DATA) to be stored in the memory cell array 100 to the bit lines (BLs). According to one embodiment, during the read operation, the page buffer circuit 210 may operate as a sense amplifier to detect data (DATA) stored in the memory cell array 100 received through the bit lines (BLs). The page buffer circuit 210 may detect data (DATA) using a read judgment voltage received from the control circuit 300. For example, the page buffer circuit 210 may determine data (DATA) by comparing a voltage level of a signal received through the bit line (BL) with the read judgment voltage.

The main voltage generator 220 may generate various types of reference voltages (RV) required to perform a program operation, a read operation, and an erase operation on the memory cell array 100 based on a main voltage control signal (MVCS). Specifically, the main voltage generator 220 may generate a word line voltage (e.g., a program voltage, a read voltage, a pass voltage, an erase verification voltage, or a program verification voltage) applied to a word line (WL), and may further generate a drain selection line voltage applied to a drain selection line (DSL) and a source selection line voltage applied to a source selection line (SSL). That is, the reference voltages (RVs) may include a word line voltage, a drain selection line voltage, and a source selection line voltage.

The row decoder 230 may select one of a plurality of memory blocks in response to a row address (X-ADDR), and may select one of the word lines (WL) of the selected memory block. The row decoder 230 may supply voltages required for a program operation, a read operation, or an erase operation for a memory cell connected to the selected word line (WL) to the word line (WL), the drain selection line (DSL), and the source selection line (SSL) using the reference voltages (RVs).

The source voltage generator 240 may generate a source voltage (SV) for performing a program operation, a read operation, and an erase operation on the memory cell array 100 based on a source voltage control signal (SVCS). Specifically, the source voltage generator 240 may generate a source voltage (SV) to be applied to a source line. The source voltage generator 240 may independently provide a source voltage (SV) to each of the plurality of memory blocks (MB1 to MBm). According to one embodiment, the source voltage generator 240 may provide different source voltages (SV) to a selected memory block and an unselected memory block from among the plurality of memory blocks (MB1 to MBm).

The control circuit 300 may output internal control signals for programming (writing) data (DATA) in the memory cell array 100 or reading data (DATA) from the memory cell array 100 based on the command (CMD), the address (ADDR), and the control signal (CTRL).

The control circuit 300 may include a memory control circuit 310, an internal memory 320, and an error correction code (ECC) circuit 330.

The memory control circuit 310 may generate a main voltage control signal (MVCS) for controlling the level of the reference voltages (RV) generated by the main voltage generator 220 based on the command (CMD) and the control signal (CTRL).

The memory control circuit 310 may generate a source voltage control signal (SVCS) for controlling the level of the source voltage (SV) generated by the source voltage generator 240. The memory control circuit 310 may generate a source voltage control signal (SVCS) corresponding to the corresponding memory block based on a block closed ratio (BCR) corresponding to each of the plurality of memory blocks (MB1 to MBm) or a block closed ratio (BCR) corresponding to each of strings (STR1 to STR4). The BCR refers to a ratio of the corresponding memory block (or the corresponding string) in a programmed page. Specifically, the BCR may refer to a ratio of the corresponding memory block or the corresponding string in a programmed page.

According to one embodiment, the memory control circuit 310 may calculate a BCR corresponding to a memory block (MB) using the following equation 1.

$$Block Closed Ratio ( BCR ) = \frac{Number of Programmed Pages of Memory Block}{Total number of Pages of Memory Block} \qquad [ Equation 1 ]$$

That is, the BCR corresponding to the memory block (MB) may refer to a ratio of programmed pages in the corresponding memory block, and may be a value obtained by dividing the number of programmed pages of the memory block by the total number of pages of the memory block.

In the example of FIG. 3, the BCR corresponding to the memory block (MB) may be a value (0.56) obtained by dividing the number (18) of programmed pages of the memory block (MB) by the total number (32) of pages of the memory block (MB).

According to another embodiment, the memory control circuit 310 may calculate a BCR corresponding to a string using the following equation 2.

$$Block Closed Ratio ( BCR ) = \frac{Number of Programmed Pages of String}{Total number of Pages of String} \qquad [ Equation 2 ]$$

That is, the BCR corresponding to a string may refer to a ratio of programmed pages in the corresponding string, and may be a value obtained by dividing the number of programmed pages of the string by the total number of pages of the string.

In the example of FIG. 3 (which is described herein below with greater detail), the BCR corresponding to the first string (STR1) may be a value (0.62) obtained by dividing the number (5) of programmed pages of the first string (STR1) by the total number (8) of pages of the first string (STR1).

The BCR corresponding to the third string (STR3) may be a value (0.5) obtained by dividing the number (4) of programmed pages of the third string (STR3) by the total number (8) of pages of the third string (STR3).

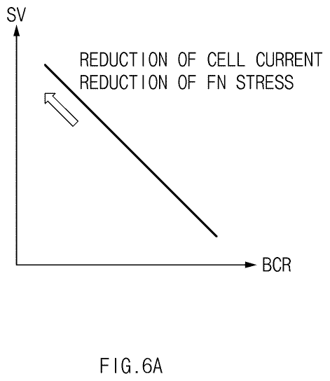

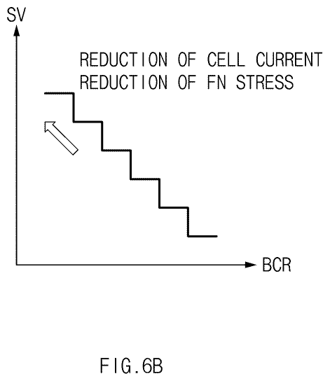

The specific operation of controlling the source voltage control signal (SVCS) using the BCR will be described later with reference to FIG. 6A, etc.

The BCR corresponding to each of the plurality of memory blocks (MB1 to MBm) may be stored in the internal memory (e.g., RAM) 320 and referenced by the memory control circuit 310. According to another embodiment, the BCR corresponding to each of the plurality of memory blocks (MB1 to MBm) may be stored in pre-allocated regions of the memory cell array 100 and referenced by the memory control circuit 310.

The memory control circuit 310 may provide a row address (X-ADDR) for selecting a word line (WL) to the row decoder 230 based on the address (ADDR), and may also provide a column address (Y-ADDR) for selecting a bit line (BL) to the page buffer circuit 210 based on the address (ADDR).

The memory control circuit 310 may calculate the number of fail bits for a specific memory block (e.g., an open block). In this instance, the open block may be a memory block in which some pages among the pages included in the memory blocks (MB1 to MBm) are programmed and the remaining pages are not programmed. In other words, the open block may include at least one programmed page and at least one erased page. In addition, the number of fail bits may denote the number of different bits as a result of comparing data programmed in a specific memory block (or a specific page) with data read from the specific memory block (or the specific page).

The memory control circuit 310 may compare the calculated number of fail bits with the threshold number of fail bits. When the number of fail bits is greater than or equal to the threshold number of fail bits, the memory control circuit 310 may perform a dummy program operation on some pages of the specific memory block. In this case, the dummy program operation may mean an operation of programming some pages of the specific memory block without a program command from an external source (e.g., a memory controller 20).

The threshold number of fail bits may be a value determined in consideration of the error correction capability of the ECC circuit 330, and may be a value that is less by a predetermined ratio than the number of fail bits that enable (or cause) uncorrectable error correction code(s) (UECC) to occur in the ECC circuit 330. According to one embodiment, the predetermined ratio may be determined in consideration of the reliability level required for the memory device 10, the remaining memory capacity, etc. For example, the predetermined ratio may be 70%, but the scope of the present disclosure is not limited thereto.

The internal memory 320 may store information necessary for controlling the memory control circuit 310, and may transmit the stored information to the memory control circuit 310 based on a request from the memory control circuit 310. According to one embodiment, the internal memory 320 may store at least one of the BCR and the threshold number of fail bits (also referred to as the limit number of fail bits) corresponding to each of the plurality of memory blocks (MB1 to MBm).

The internal memory 320 may be a volatile memory (e.g., a dynamic random access memory DRAM) or a nonvolatile memory (e.g., a one-time programmable memory OTP).

The ECC circuit 330 may detect an error in data read from the memory cell array 100, and may correct the error using an error correction code (ECC). According to one embodiment, the ECC circuit 330 may correct the error using coded modulation. For example, the coded modulation may include at least one of a low density parity check (LDPC) code, a Bose, Chaudhuri, Hocquenghem (BCH) code, a turbo code, a Reed-Solomon code, a convolutional code, a recursive systematic code (RSC), trellis-coded modulation (TCM), block coded modulation (BCM), and a Hamming code.

The threshold number of fail bits may be calculated by the ECC circuit 330 or may be calculated by the memory control circuit 310, so that the calculated threshold number of fail bits can be stored in the internal memory 320.

The BCR and the threshold number of limit fail bits may be collectively referred to as characteristic information of the corresponding memory block. The characteristic information is information related to the reliability of the memory block. The control circuit 300 may generate and store characteristic information for each of the memory blocks (MB1 to MBm), and may control, via (for example, instructions provided to) the peripheral circuit 200, each of the memory blocks (MB1 to MBm) based on the characteristic information.

FIG. 3 is a schematic diagram illustrating an example of the memory block shown in FIG. 2 according to an embodiment of the present disclosure.

Referring to FIG. 3, the memory block (MB) may correspond to one example of the plurality of memory blocks (MB1 to MBm) illustrated in FIG. 2.

The memory block (MB) may have a 3D NAND structure in which memory cells are arranged in three directions (including a first direction X, a second direction Y, and a third direction Z).

The memory block (MB) may include first to 32^{nd} pages (PG1 to PG32). The first to 32^{nd} pages (PG1 to PG32) may be arranged in a matrix shape including eight rows and four columns. In addition, the first to 32^{nd} pages (PG1 to PG32) may correspond to the first to 32^{nd} word lines (WL1 to WL32), respectively. The columns of the memory block (MB) may correspond to the plurality of strings (STR1 to STR4), respectively. According to another embodiment, the first to 32^{nd} pages (PG1 to PG32) may be divided into eight groups by grouping pages belonging to the same row, and each group (e.g., a group including PG1 to PG4) may correspond to one word line.

Each of the first to 32^{nd} pages (PG1 to PG32) may correspond to one of the first to fourth strings (STR1 to STR4). As illustrated in FIG. 3, the first strings (STR1) may correspond to the first, fifth, ninth, thirteenth, seventeenth, twenty-first, twenty-fifth, and twenty-ninth pages (PG1, PG5, PG9, PG13, PG17, PG21, PG25, PG29). The second strings (STR2) may correspond to the second, sixth, tenth, fourteenth, eighteenth, twenty-second, twenty-sixth, and thirtieth pages (PG2, PG6, PG10, PG14, PG18, PG22, PG26, PG30). The third strings (STR3) may correspond to the third, seventh, eleventh, fifteenth, nineteenth, twenty-third, twenty-seventh, and thirty-first pages (PG3, PG7, PG11, PG15, PG19, PG23, PG27, PG31). The fourth strings (STR4) may correspond to the fourth, eighth, twelfth, sixteenth, twentieth, twenty-fourth, twenty-eighth, and thirty-second pages (PG4, PG8, PG12, PG16, PG20, PG24, PG28, PG32).

Each of the first to 32^{nd} word lines (WL1 to WL32) may extend in the first direction (X). In addition, memory cells connected to each of the first to 32^{nd} word lines (WL1 to WL32) may also extend in the first direction (X).

Memory cells respectively included in pages (e.g., PG1 to PG4) belonging to the same row among the first to 32^{nd} pages (PG1 to PG32) and arranged in one row along the second direction (Y) may be connected to the same bit line. Each bit line may extend in the second direction (Y).

Memory cells respectively included in pages (e.g., PG1, PG5, PG9, PG13, PG17, PG21, PG25, PG29) belonging to the same column among the first to 32^{nd} pages (PG1 to PG32) and arranged in one row in the third direction (Z) may be connected to the same string (STR1 to STR4). Memory cells connected to the same string (STR1 to STR4) may be connected in series. Each of the first to fourth strings (STR1 to STR4) may include a plurality of strings, and the number of strings included in each of the strings (STR1 to STR4) may be equal to the number of bit lines.

It is assumed that the first to eighteenth pages (PG1 to PG18) among the first to 32^{nd} pages (PG1 to PG32) included in the memory block (MB) are programmed, and the remaining pages (PG19 to PG32) are not programmed. In other words, the memory block (MB) may be an open block. According to an embodiment, a program operation for the memory block (MB) may be sequentially performed from the first page (PG1).

For example, when a read operation is performed for one of the pages (PG1, PG5, PG9, PG13, PG17) connected to the first string (STR1), a read voltage may be applied to a selected word line among the word lines (WL1 to WL5), and a pass voltage may be applied to the unselected word lines. Among the unselected word lines, the non-programmed pages (PG21, PG25, PG29) may contain erased cells, and when a relatively high pass voltage (caused by ‘read stress’) is repeatedly applied to the erased cells (read stress), electrons may flow into a charge trap layer (CTL) of each of the erased cells due to the Fowler-Nordheim (FN) stress, thereby increasing a threshold voltage of each of the erased cells. When a program operation is performed on the non-programmed pages (PG21, PG25, PG29) after the threshold voltage of the erased cells has increased as described above, a margin between the threshold voltage distribution before the program operation and the other threshold voltage distribution after the program operation in the non-programmed pages (PG21, PG25, PG29) may decrease, which may cause a read disturbance phenomenon in which the program operation is not performed normally.

Meanwhile, due to characteristics of the 3D NAND structure, memory cells that are arranged in the third direction (Z) and included in pages (e.g., PG1, PG5, PG9, PG13, PG17, PG21, PG25, PG29) connected to the same string (e.g., STR1) may be connected in series, and the CTLs of the memory cells that are connected in series may be formed integrally with each other.

For example, the CTL of the programmed cell of the programmed seventeenth page (PG17) and the CTL of the erased cell of the unprogrammed (i.e., erased) 21^{st} page (PG21) may be connected while being adjacent to each other. Relatively more electrons are trapped in the CTL of the programmed cell of the programmed seventeenth page (PG17), and relatively more holes are trapped in the CTL of the erased cell of the erased 21^{st} page (PG21). As a result, electrons trapped in the CTL of the programmed cell of the seventeenth page (PG17) may be lost, thereby changing a threshold voltage distribution of the corresponding programmed cell.

That is, when the programmed page and the erased page are located adjacent to each other, there may occur a lateral retention phenomenon in which the CTL of the erased cell adversely affects the retention characteristics of the CTL of the programmed cell.

The number of pages, the number of word lines included in one memory block (MB) described in FIG. 3, the number of strings included in one memory block (MB), and the number of bit lines included in one memory block (MB) are merely examples for convenience, and the number of pages included in the memory block (MB), the number of word lines included in the memory block (MB), the number of strings included in the memory block (MB), and the number of bit lines included in the memory block (MB) may vary based on different embodiments.

FIG. 4 is a circuit diagram illustrating example operations of strings shown in FIG. 3 based on some embodiments of the present disclosure.

Referring to FIG. 4, the string circuit 400 may include a string 410 included in one of the first to fourth strings (STR1 to STR4) illustrated in FIG. 3, and a page buffer 420 connected to the string 410.

The string 410 may include a drain selection transistor (DST), a plurality of memory cells, and a source selection transistor (SST) that are connected in series.

The drain selection transistor (DST) may be an N-channel MOSFET (NMOS) transistor connected between the bit line (BL) and the memory cells. The gate of the drain selection transistor (DST) may be connected to the drain selection line (DSL), and the drain selection transistor (DST) may be turned on or off depending on the voltage of the drain selection line (DSL).

According to the example of FIG. 3, the plurality of memory cells may correspond to eight memory cells. The plurality of memory cells may be connected in series between the drain selection transistor (DST) and the source selection transistor (SST).

FIG. 4 illustrates a selected memory cell (MCn) (where ‘n’ is an integer greater than or equal to 2) among a plurality of memory cells, and non-selected memory cells (MC(n−1), MC(n+1)) that are adjacent to the selected memory cell (MCn). The gates of the plurality of memory cells may be connected to the corresponding word lines, and program operations, read operations, and erase operations may be performed according to the voltage of the word lines. The word line connected to the selected memory cell (MCn) may be defined as a selected word line (Sel WL), and the word lines connected to the non-selected memory cells (MC(n−1), MC(n+1)) may be defined as non-selected word lines (Unsel WL). The remaining memory cells except for the selected memory cell (MCn) among the plurality of memory cells may be non-selected memory cells, and the word lines connected to the non-selected memory cells may also be defined as non-selected word lines.

Each of the plurality of memory cells may be a single-level cell (SLC), a multi-level cell (MLC), a triple-level cell (TLC), a quad-level cell (QLC), or a memory cell capable of storing 5 or more bits of data. In some embodiments, for convenience, it is assumed that each of the plurality of memory cells is a single-level cell (SLC). Each of the plurality of memory cells may include a CTL that traps charges between the channel layer and the word line.

The source selection transistor (SST) may be an NMOS transistor connected between the source line (SL) and the memory cells. The gate of the source selection transistor (SST) may be connected to the source selection line (SSL), and the source selection transistor (SST) may be turned on or off depending on the voltage of the source selection line (SSL). The source line (SL) may transmit the source voltage (SV) received from the source voltage generator 240 of FIG. 2 to the source selection transistor (SST).

The page buffer 420 may detect and store data stored in a plurality of memory cells.

The page buffer 420 may include a bit line capacitor (CBL), a page buffer transistor (PBX), a sensing node capacitor (Cso), and a latch 430.

The bit line capacitor (CBL) may be connected between the bit line (BL) and a ground voltage (VSS) to stabilize the voltage of the bit line (BL). Here, the stabilization operation may be an operation to reduce noise (e.g., high frequency noise) introduced into the bit line (BL).

The page buffer transistor (PBX) may be an NMOS transistor connected between the bit line (BL) and the sensing node (SO). The gate of the page buffer transistor (PBX) may receive a page buffer control signal (PBSENSE) from the control circuit 300, and the page buffer transistor (PBX) may precharge the bit line (BL) according to the page buffer control signal (PBSENSE), or may control the bit line (BL) and the sensing node (SO) to be electrically connected to each other so that a voltage change of the bit line (BL) can be detected by the sensing node (SO).

A sensing node capacitor (Cso) may be connected between the sensing node (SO) and the ground voltage (VSS) to stabilize the voltage of the sensing node (SO). In this embodiment, the stabilization operation may be an operation to reduce noise (e.g., high-frequency noise) introduced into the sensing node (SO).

The latch 430 may detect a voltage of the sensing node (SO) and store data corresponding to the voltage of the sensing node (SO). The data stored in the latch 430 may be output to the outside according to the control of the control circuit 300. According to one embodiment, the latch 430 may include a sense-amplifier and an inverter-type latch, but the scope of the present disclosure is not limited thereto.

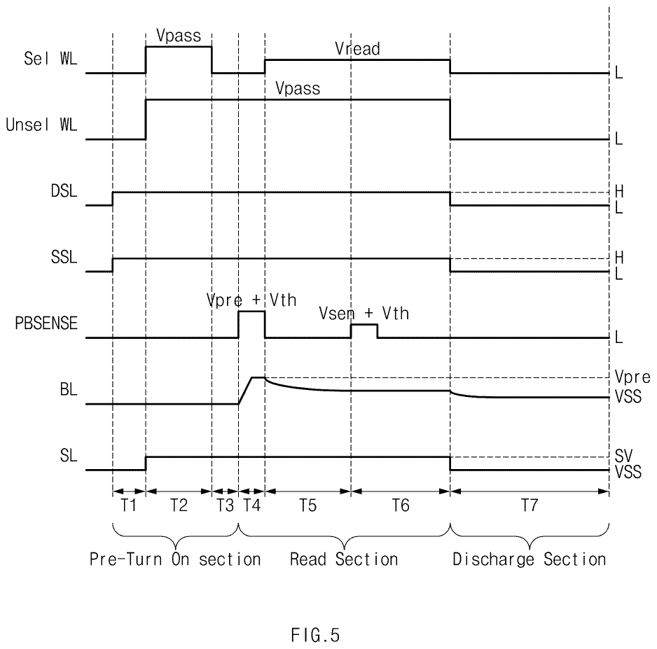

FIG. 5 is a timing diagram illustrating an example of the read operation of the string circuit 400 shown in FIG. 4 based on some embodiments of the present disclosure.

Referring to FIG. 5, the read operation of the string circuit 400 is an operation of reading data stored in one of the plurality of memory cells of the string circuit 400, and may include a pre-turn on section, a read section, and a discharge section.

In FIG. 5, the voltage applied to turn off each transistor may be defined as a logic low voltage (L), and the voltage applied to turn on each transistor may be defined as a logic high voltage (H).

The pre-turn-on section may include first to third time periods (T1 to T3).

During the first time period (T1), as the voltage of the drain selection line (DSL) and the voltage of the source selection line (SSL) transitions from a logic low voltage (L) to a logic high voltage (H), each of the drain selection transistor (DST) and the source selection transistor (SST) may be turned on.

During the second time period (T2), a pass voltage (Vₚₐₛₛ) may be applied to each of the selected word line (Sel WL) and the unselected word line (Unsel WL). The pass voltage (Vₚₐₛₛ) may be a voltage greater than the threshold voltages of memory cells programmed with an arbitrary program voltage, and the selected memory cell (MCn) and unselected memory cells (MC(n−1), MC(n+1), etc.) to which the pass voltage (Vₚₐₛₛ) is applied may be turned on. Accordingly, the channel layers of the drain selection transistor (DST), the source selection transistor (SST), the selected memory cell (MCn), and the non-selected memory cells (MC(n−1), MC(n+1), etc.) can be initialized. In this instance, initialization may refer to an operation of removing the remaining charges that have been introduced into the channel layers of the drain selection transistor (DST), the source selection transistor (SST), the selected memory cell (MCn), and the non-selected memory cells (MC(n−1), MC(n+1), etc.) through the source line (SL) during a previous program operation or a read operation, etc.

While the pass voltage (Vₚₐₛₛ) is applied to each of the unselected word lines (Unsel WL), the source voltage (SV) generated by the source voltage generator 240 may be applied to the source line (SL). The source voltage (SV) may be the same as the ground voltage (VSS) or may be a voltage that is greater than the ground voltage (VSS) by a predetermined voltage. However, FIG. 5 shows an embodiment in which the source voltage (SV) is greater than the ground voltage (VSS). The method of determining the source voltage (SV) will be described later with reference to FIGS. 6A and 6B.

The source voltage for minimizing the read disturbance phenomenon may be applied to the memory device at the third time period (T3) in consideration of the following to reduce the number (for example, amount) of electrons introduced into the CTL of the erased cell. The potential difference between the gate and the channel layer of the erased cell among the unselected memory cells is largest at a time when the pass voltage (Vₚₐₛₛ) is applied to the unselected memory cells, so that many more electrons that may cause (or amplify) the read disturbance phenomenon may be introduced into the CTL of the erased cell. When a source voltage (SV) greater than the ground voltage (VSS) is supplied to the memory device through the source line (SL), the potential difference between the gate and the channel layer of the erased cell may be reduced by increasing the potential of the channel layer of the erased cell, thereby reducing the amount of electrons to be introduced into the CTL of the erased cell.

In addition, the source voltage (SV) may be continuously supplied to the source line (SL) while the pass voltage (Vₚₐₛₛ) is applied to the unselected memory cells to prevent electrons from being introduced into the CTL of the erased cell.

According to another embodiment, the time point at which the source voltage (SV) is applied to the source line (SL) may be an arbitrary time point (e.g., a start time of the fourth time period T4) after the pass voltage (Vₚₐₛₛ) is applied to the unselected memory cells.

However, a time section (period) in which the source voltage (SV) is applied to the source line (SL) may overlap at least partly with a time section (period) in which the pass voltage (Vₚₐₛₛ) is applied to the unselected memory cell (e.g., MC(n+1)) of the corresponding string.

At the third time period (T3), a logic low voltage (L) may be applied to each of the drain selection line (DSL), the source selection line (SSL), the selected word line (Sel WL), and the unselected word line (Unsel WL). Accordingly, each of the drain selection transistor (DST), the source selection transistor (SST), the selected memory cell (MCn), and the unselected memory cells (MC(n−1), MC(n+1), etc.) can be turned off.

That is, a pre-turn-on section including the first to third time periods (T1 to T3) may be a time section for initializing the channel layer of the transistors constituting the string 410.

The read section may include the fourth to sixth time periods (T4 to T6).

At the fourth time period (T4), the page buffer control signal (PBSENSE) may transition from a logic low voltage (L) to a voltage that is the sum of the precharge voltage (Vpre) and the threshold voltage (Vth). In this instance, the threshold voltage (Vth) may denote the threshold voltage of the page buffer transistor (PBX). Accordingly, the page buffer transistor (PBX) may be turned on and the bit line (BL) may be precharged with the precharge voltage (Vpre).

At the fifth time period (T5), the page buffer control signal (PBSENSE) may transition to the logic low voltage (L) again so that the page buffer transistor (PBX) can be turned off. A read voltage (Vread) may be applied to the selected memory cell (MCn), so that a cell current corresponding to whether (for example, indicating whether) the selected memory cell (MCn) is programmed can flow between the bit line (BL) and the source line (SL). If the selected memory cell (MCn) is programmed, the selected memory cell (MCn) may be turned off to allow only a relatively low cell current to flow, and thus the degree of voltage drop of the bit line (BL) may be relatively small. On the other hand, if the selected memory cell (MCn) is not programmed (i.e., is erased), the selected memory cell (MCn) is turned on so that a relatively high cell current flows, and thus the degree of the voltage drop of the bit line (BL) may be relatively large.

At the sixth time period (T6), the page buffer control signal (PBSENSE) may transition from a logic low voltage (L) to a voltage that is the sum of the sensed voltage (Vsen) and the threshold voltage (Vth). In some embodiments, the sensed voltage (Vsen) may be a voltage for determining whether a program or erase operation is performed in the page buffer 420. Accordingly, the page buffer transistor (PBX) may be turned on so that the bit line (BL) may have a voltage greater or less than the sensed voltage (Vsen) depending on whether the selected memory cell (MCn) is programmed.

If the selected memory cell (MCn) is programmed and the degree of voltage drop of the bit line (BL) is relatively small, the bit line (BL) may have a voltage greater than the sensed voltage (Vsen). On the other hand, if the selected memory cell (MCn) is not programmed and the degree of voltage drop of the bit line (BL) is relatively large, the bit line (BL) may have a voltage less than the sensed voltage (Vsen).

The voltage of this bit line (BL) may be transmitted to the sensing node (SO) through the turned-on page buffer transistor (PBX), and the latch 430 may detect the voltage of the sensing node (SO) and store data corresponding to the voltage of the sensing node (SO).

That is, the read section may include a fourth time period (T4) for precharging the bit line (BL), a fifth time period (T5) for setting a voltage corresponding to data stored in the selected memory cell (MCn) to the bit line (BL), and a sixth time period (T6) for detecting the voltage of the bit line (BL) and storing data.

In the seventh time period (T7) corresponding to the discharge section, a logic low voltage (L) may be applied to each of the drain selection line (DSL), the source selection line (SSL), the selected word line (Sel WL), and the unselected word line (Unsel WL). Accordingly, each of the drain selection transistor (DST), the source selection transistor (SST), the selected memory cell (MCn), and the unselected memory cells (MC(n−1), MC(n+1), etc.) may be turned off. In addition, since the pass voltage (Vₚₐₛₛ) is not applied to the unselected word line (Unsel WL), the ground voltage (VSS) instead of the source voltage (SV) may be applied to the source line (SL).

In some embodiments, a discharge circuit connected to the bit line (BL) may operate to control the bit line (BL) to have a ground voltage (VSS).

FIG. 6A is a diagram illustrating an example of a method for determining the source voltage (SV) described in FIG. 5 in accordance with an embodiment of the present disclosure.

More particularly, referring to FIG. 6A, a graph for explaining an example of a method for determining the level of the source voltage (SV) controlled by the memory control circuit 310 is illustrated.

As described in FIG. 3, the BCR (block closed ratio) may be a BCR corresponding to each of the plurality of memory blocks (MB1 to MBm) or a BCR corresponding to each of the strings (STR1 to STR4).

In the graph of FIG. 6A, the X-axis may correspond to the BCR, and the Y-axis may correspond to the source voltage (SV). As illustrated in the graph of FIG. 6A, the BCR and the source voltage (SV) may have an inversely proportional linear relationship. That is, as the BCR increases, the source voltage (SV) may decrease, and as the BCR decreases, the source voltage (SV) may increase.

When the BCR decreases, as the ratio of programmed pages decreases, the number of programmed cells included in the string may decrease and the number of erased cells in the string may increase. As the number of erased cells increases relatively, the probability of occurrence of the read disturbance phenomenon due to FN stress increases, so that the FN stress can be reduced by increasing the source voltage (SV) to increase the potential of the channel layer of each of the memory cells included in the string.

In addition, when the same pass voltage (Vₚₐₛₛ) is applied to the programmed cell and the erased cell, the cell current flowing in the erased cell having a relatively large number of holes included in the CTL may be greater than the cell current flowing in the programmed cell having a relatively large number of electrons included in the CTL. Therefore, when the BCR decreases, as the ratio of erased cells included in the string increases, the cell current flowing in the string during the read operation may increase, and as the threshold voltage distribution of the selected memory cell is shifted, there may be a possibility that data of the selected memory cell may be read incorrectly. However, as shown in FIG. 6A, when the BCR decreases, the potential of the channel layers of the memory cells included in the string may increase by increasing the source voltage (SV), thereby reducing the cell current flowing in the string. Accordingly, the shifting of the threshold voltage distribution of the selected memory cell may be minimized, thereby reducing the possibility of misreading data of the selected memory cell.

The memory control circuit 310 may calculate a BCR corresponding to a memory block or a string including a selected memory cell that is a target of the read operation, and may determine a level of the source voltage (SV) corresponding to the calculated BCR based on the linear relationship illustrated in FIG. 6A to generate a source voltage control signal (SVCS). According to one embodiment, a mapping table indicating a relationship between the BCR and the source voltage (SV) may be stored in the internal memory 320, and may be referenced by the memory control circuit 310.

The slope of the straight line indicating the relationship between the BCR and the source voltage (SV) may be experimentally determined by considering the intensity of the FN stress, the degree to which the threshold voltage distribution of the selected memory cell is shifted, etc.

FIG. 6B is a diagram illustrating another example of a method for determining the source voltage (SV) described in FIG. 5 based on some embodiments of the present disclosure.

Referring to FIG. 6B, a graph for explaining another example of a method for determining the level of the source voltage (SV) controlled by the memory control circuit 310 is illustrated.

In the graph of FIG. 6B, the X-axis may correspond to the BCR, and the Y-axis may correspond to the source voltage (SV). As illustrated in the graph of FIG. 6B, the BCR and the source voltage (SV) may change stepwise while being inversely proportional to each other. That is, as the BCR increases, the source voltage (SV) may be maintained constant and then decreased by a predetermined offset voltage, and then the source voltage may be maintained constant and then decreased by a predetermined offset voltage. In this way, the above-described process may be repeated as described above. Conversely, as the BCR decreases, the source voltage (SV) may be maintained constant and then increased by a predetermined offset voltage, and then the source voltage (SV) may be maintained constant and then increased by a predetermined offset voltage. In this way, the above-described process may be repeated as described above.

The effect of the BCR and the source voltage (SV) having an inversely proportional relationship has been described with reference to FIG. 6A, and such redundant description thereof will herein be omitted for brevity.

When the BCR and the source voltage (SV) change stepwise as in the graph of FIG. 6B, the relationship between the BCR and the source voltage (SV) can be simplified. As a result, the complexity of the mapping table representing the relationship between the BCR and the source voltage (SV) can be reduced, and system resources (e.g., the capacity of the internal memory 320) required for storing the mapping table can be reduced.

The memory control circuit 310 may calculate a BCR corresponding to a memory block or a string including a selected memory cell that is a target of the read operation, and may determine a level of the source voltage (SV) corresponding to the calculated BCR based on the stepwise relationship illustrated in FIG. 6B to generate a source voltage control signal (SVCS). The offset voltage at which the source voltage (SV) changes and the width of the BCR at which the source voltage (SV) is maintained constant can be experimentally determined by considering the intensity of the FN stress, the degree to which the threshold voltage distribution of the selected memory cell is shifted, the system resources that can store the mapping table, and the like.

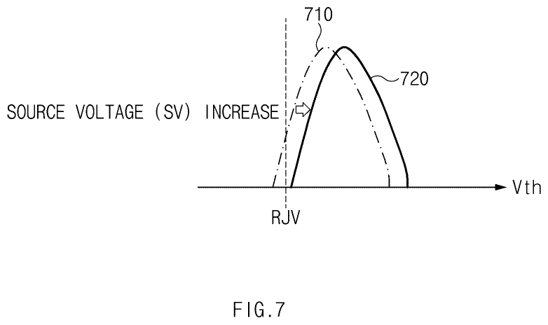

FIG. 7 is a diagram illustrating the result of comparison between threshold voltage distributions of an open block and a closed block based on some embodiments of the present disclosure.

Referring to FIG. 7, a first threshold voltage distribution 710 in which a memory cell included in an open block is programmed with a specific program voltage and a second threshold voltage distribution 720 in which a memory cell included in a closed block is programmed with a specific program voltage are illustrated. Here, the closed block may be a memory block in which all pages contained in the memory block are programmed.

As described in FIG. 6A, when the same pass voltage (Vₚₐₛₛ) is applied to the programmed cell and the erased cell, the cell current flowing in the erased cell having a relatively large number of holes included in the CTL may be greater than the cell current flowing in the programmed cell having a relatively large number of electrons included in the CTL. When the ratio of erased cells included in the string increases, the cell current flowing in the string during the read operation may increase, so that the threshold voltage distribution of the selected memory cell can be shifted. Accordingly, the first threshold voltage distribution 710 may be shifted to the left compared to the second threshold voltage distribution 720.

In principle, the first threshold voltage distribution 710 and the second threshold voltage distribution 720 should be off-cells based (for example, based only on an ideal voltage distribution associated with the off-cells) on the read judgment voltage (RJV), but since the first threshold voltage distribution 710 of the open block is shifted, there may be a possibility that data of the corresponding memory cell may be read incorrectly.

However, as described in FIG. 6A, as the BCR decreases, the potential of the channel layers of the memory cells included in the string can be increased by increasing the source voltage (SV), thereby reducing the cell current flowing in the string. Accordingly, the first threshold voltage distribution 710 of the selected memory cell of the open block may be shifted to be the same as or close to the second threshold voltage distribution 720, thereby reducing the possibility of misreading data of the selected memory cell.

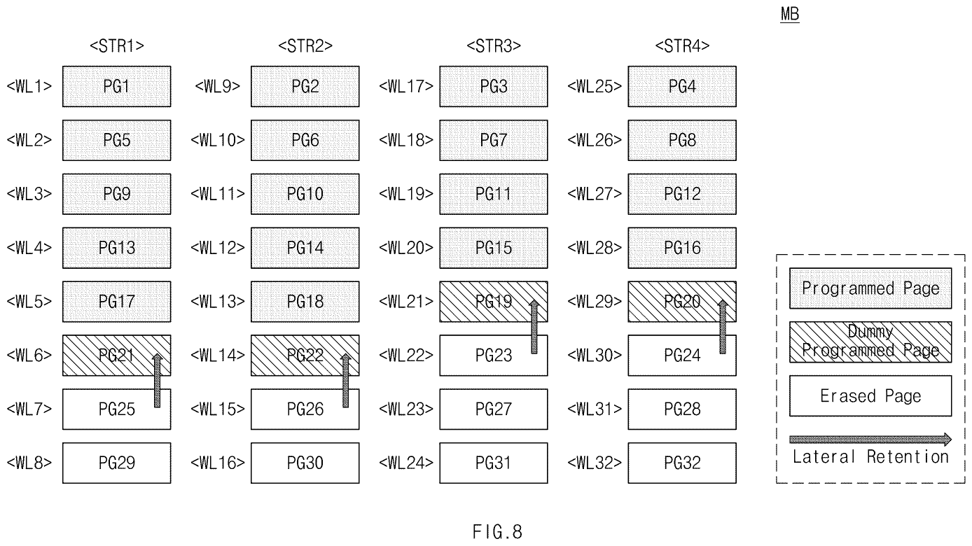

FIG. 8 is a schematic diagram illustrating an example of a dummy program operation performed by the memory control circuit shown in FIG. 2 in accordance with embodiments of the present disclosure.

Referring to FIG. 8, an example in which a dummy program operation is performed on the memory block (MB) described in FIG. 3 is illustrated.

As shown in FIG. 3, when the first to eighteenth pages (PG1 to PG18) are programmed pages and the nineteenth to thirty-second pages (PG19 to PG32) are erased pages, the seventeenth programmed page (PG17) may cause the lateral retention phenomenon due to the twenty-first erased page (PG21), the eighteenth programmed page (PG18) may cause the lateral retention phenomenon due to the twenty-second erased page (PG22), the fifteenth programmed page (PG15) may cause the lateral retention phenomenon due to the nineteenth erased page (PG19), and the sixteenth programmed page (PG16) may cause the lateral retention phenomenon due to the 20th erased page (PG20).

The memory control circuit 310 may calculate the number of fail bits for a memory block (MB) serving as an open block. According to one embodiment, the number of fail bits may be calculated for the entire memory block (MB). According to another embodiment, the number of fail bits may be calculated for pages (e.g., PG15 to PG18) adjacent to erased pages among pages included in a memory block (MB). Here, the memory block (MB) that is a target of calculation of the number of fail bits, or the pages (e.g., PG15 to PG18) adjacent to erased pages among pages included in the memory block (MB) may be collectively referred to as monitoring targets. In the present disclosure, the expression “A is adjacent to B” may mean that A is located closest to B among a group of candidates including “B”.

Since the lateral retention phenomenon has unique characteristics of worsening over time, the calculation of the number of fail bits and the determination of whether to perform the dummy program operation can be performed periodically.

The number of fail bits may denote the number of different bits determined by comparing data programmed in the monitoring target with data read from the monitoring target.

According to one embodiment, the read data may be all or part of the data of each memory cell. For example, if each of the plurality of memory cells is a triple-level cell (TLC), the read data may be at least one of the least significant bit (LSB), the central significant bit (CSB), and the most significant bit (MSB).

According to another embodiment, the read data may be data that has been read using some (e.g., R3) of the plurality of read judgment voltages (e.g., R1 to R7) for reading data of each memory cell.

If the read data is not the entire data but a part of data, time and power consumption required to determine whether to perform the dummy program operation may be reduced.

The memory control circuit 310 may compare the calculated number of fail bits with the threshold number of fail bits. If the number of fail bits is greater than or equal to the threshold number of fail bits, the dummy program operation can be performed on some pages of a specific memory block.

According to one embodiment, pages to be used as a target of the dummy program operation may range from the next page of the last programmed page to another page having a serial number (page number) corresponding to a sum value obtained by adding the total number of strings of the memory block (MB) to a serial number of the last programmed page. In other words, the dummy program operation may be performed on erased pages adjacent to the programmed pages among the erased pages in the memory block (MB). In addition, the number of pages on which the dummy program operation is performed may be the same as the number of strings of the memory block (MB).

For example, in the example of FIG. 8, pages to be used as the target of the dummy program operation may range from the next page (PG19) of the last programmed page (PG18) to another page having a serial number (22) corresponding to a sum value (22) obtained by adding the total number (4) of strings of the memory block (MB) to a serial number (18) of the last programmed page (PG18). That is, in the example of FIG. 8, the dummy program operation may be performed on four pages from the nineteenth to twenty-second pages (PG19 to PG22).

When the dummy program operation is performed, the lateral retention phenomenon may occur in the nineteenth to twenty-second pages (PG19 to PG22), not in the fifteenth to eighteenth pages (PG15 to PG18). Since the nineteenth to twenty-second pages (PG19 to PG22) are not pages in which normal data is programmed, it is okay for the lateral retention phenomenon to occur in the nineteenth to twenty-second pages (PG19 to PG22). Therefore, the lateral retention phenomenon for the fifteenth to eighteenth pages (PG15 to PG18) in which normal data is programmed can be prevented through the dummy program operation.

In addition, the dummy program operation is performed only in the nineteenth to twenty-second pages (PG19 to PG22) corresponding to a minimum number of pages that can prevent the lateral retention phenomenon for the fifteenth to eighteenth pages (PG15 to PG18), not the entire erased pages (PG19 to PG32), thereby minimizing waste of data storage space (i.e., pages).

According to another embodiment, pages to be used as a target of the dummy program operation may range from the next page of the last programmed page to another page having a serial number corresponding to a sum value obtained by adding a value (e.g., a value that is twice the total number of strings) exceeding the total number of strings of the memory block (MB) to a serial number of the last programmed page.

According to one embodiment, the dummy program operation may be performed by a method of programming a single-level cell (SLC). That is, the dummy program operation may be an operation of performing programming once using a specific program voltage. As a result, time and power to be consumed for the dummy program operation can be minimized.

According to one embodiment, the memory control circuit 310 may determine the program voltage to be used for the dummy program operation according to a retention vulnerability indicating a possibility that lateral retention may occur. For example, the retention vulnerability may represent a value obtained by subtracting the threshold number of fail bits from the number of fail bits, or may represent a difference between the number of fail bits and the threshold number of fail bits.

As the retention vulnerability increases, the possibility of lateral retention increases, so that the memory control circuit 310 can increase the program voltage to be used for the dummy program operation so that many more electrons can be trapped in the CTL of the dummy programmed page. Accordingly, the retention characteristic change due to holes trapped in the CTL of the erased page can be prevented from affecting the programmed page.

On the other hand, as the retention vulnerability decreases, the possibility of lateral retention decreases, so that the memory control circuit 310 can decrease the program voltage to be used for the dummy program operation so that relatively fewer electrons can be trapped in the CTL of the dummy programmed page. Accordingly, the retention characteristic change due to holes trapped in the CTL of the erased page can be prevented from affecting the programmed page while preventing unnecessary power consumption.

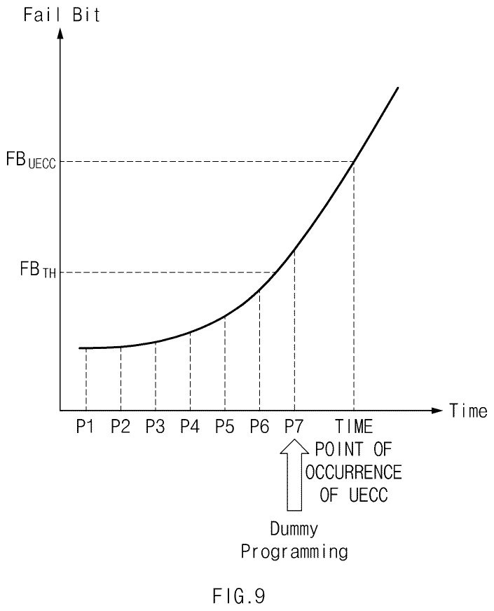

FIG. 9 is a diagram showing changes in fail bits over time in a monitoring target in accordance with embodiments of the present disclosure.

Referring to FIG. 9, the relationship between time and the number of fail bits (i.e., the amount of fail bits) occurring in a monitoring target is illustrated.

The lateral retention phenomenon may worsen over time due to attraction between electrons and holes in a CTL, repetitive read operations, etc. As shown in FIG. 9, the number of fail bits occurring in a monitoring target may increase exponentially over time. In a situation in which the number of fail bits generated in the monitoring target increases, when the number of fail bits generated in the monitoring target is less than the number (FB_{UECC}) of fail bits in which an uncorrectable error correction code (UECC) occurs, the ECC circuit 330 may correct the error. However, if the number of fail bits generated in the monitoring target is greater than the number (FB_{UECC}) of fail bits in which a UECC occurs, there may occur a UECC in which the ECC circuit 330 cannot correct the error.

The memory control circuit 310 may periodically perform calculation of the number of fail bits for the monitoring target. As illustrated in FIG. 9, calculation of the number of fail bits may be performed sequentially at each of the first to seventh time points (P1 to P7), and the interval between the time points can be experimentally determined by considering the relationship between the time and the number of fail bits generated in the monitoring target.

At each of the first to seventh time points (P1 to P7), the memory control circuit 310 may calculate the number of fail bits for the monitoring target, and may compare the calculated number of fail bits with the threshold number of fail bits (FB_{TH}) to determine whether the number of fail bits is greater than or equal to the threshold number of fail bits (FB_{TH}).

At the first to sixth time points (P1 to P6), since the number of fail bits is less than the threshold number of fail bits (FB_{TH}), the memory control circuit 310 may not perform the dummy program operation.

At the seventh time point (P7), since the number of fail bits is greater than or equal to the limit fail bit number (FB_{TH}) (i.e., the threshold number), the memory control circuit 310 may perform the dummy program operation.

As described in FIG. 8, the memory control circuit 310 may determine the program voltage to be used for the dummy program operation according to the retention vulnerability indicating the possibility of occurrence of lateral retention, and the retention vulnerability may be denoted by a value obtained by subtracting the threshold number (FB_{TH}) of fail bits from the number of fail bits calculated at the seventh time point (P7).

The threshold number (FB_{TH}) of fail bits may represent a value that is less by a predetermined ratio (e.g., 70%) than the number (FB_{UECC}) of fail bits in which UECC occurs. This is to prevent occurrence of UECC due to the lateral retention phenomenon by performing the dummy program operation in advance at an appropriate time point.

As is apparent from the above description, the semiconductor memory device according to the embodiments of the present disclosure can solve a reliability problem occurring in open blocks of a memory cell array.

While the present disclosure contains many specifics, these should not be construed as limitations on the scope of any invention or of what may be claimed, but rather as descriptions of features that may be specific to particular embodiments of particular inventions. Certain features that are described in the present disclosure in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or a variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few embodiments and examples are described and other embodiments, enhancements and variations can be made based on what is described and illustrated in the present disclosure. Furthermore, the embodiments may be combined to form additional embodiments.

What is claimed is:

1. A semiconductor memory device comprising:
a memory block including at least one programmed page and at least one erased page;
a control circuit configured to generate characteristic information for the memory block, wherein the characteristic information includes information related to reliability of the memory block; and
a peripheral circuit configured to control an operation of the memory block based on the characteristic information.

2. The semiconductor memory device according to claim 1, wherein:
the at least one programmed page and the at least one erased page are arranged in a matrix including a plurality of rows and a plurality of columns,
wherein the plurality of columns corresponds to a plurality of strings, respectively.

3. The semiconductor memory device according to claim 2, wherein:
the characteristic information includes a block closed ratio corresponding to the memory block.

4. The semiconductor memory device according to claim 3, wherein:
the block closed ratio is obtained by dividing a number of the at least one programmed page of the memory block by a total number of pages of the memory block.

5. The semiconductor memory device according to claim 3, wherein:
the block closed ratio is obtained by dividing a number of at least one programmed page of a string corresponding to a selected memory cell selected from the memory block by a total number of pages of the string.

6. The semiconductor memory device according to claim 3, wherein:
the peripheral circuit includes a source voltage generator configured to supply a source voltage to a source line connected to a string of the memory block; and
the control circuit is configured to generate a source voltage control signal for controlling a level of the source voltage based on the block closed ratio.

7. The semiconductor memory device according to claim 6, wherein:
during a read operation for a selected memory cell of the string, a time section in which the source voltage is applied to the source line overlaps with a time section in which a pass voltage is applied to an unselected memory cell of the string.

8. The semiconductor memory device according to claim 6, wherein:
during a read operation for a selected memory cell of the string, the source voltage is applied to the source line at a time point where a pass voltage is applied to an unselected memory cell of the string.

9. The semiconductor memory device according to claim 6, wherein:
the source voltage is greater than a ground voltage.

10. The semiconductor memory device according to claim 6, wherein:
the source voltage decreases as the block closed ratio increases.

11. The semiconductor memory device according to claim 6, wherein:
the source voltage and the block closed ratio have a linear relationship or a stepwise relationship with each other.

12. The semiconductor memory device according to claim 2, wherein:
the characteristic information includes a threshold number of fail bits corresponding to the memory block.

13. The semiconductor memory device according to claim 12, wherein:
the threshold number of fail bits is less by a predetermined ratio than the number of fail bits that enable uncorrectable error correction code (UECC) to occur in an error correction code (ECC) circuit of the control circuit.

14. The semiconductor memory device according to claim 12, wherein the control circuit is configured to:
compare the number of fail bits calculated for a monitoring target of the memory block with the threshold number of fail bits; and
perform a dummy program operation for the memory block when the number of fail bits is greater than or equal to the threshold number of fail bits.

15. The semiconductor memory device according to claim 14, wherein:
the monitoring target includes a programmed page adjacent to the at least one erased page.

16. The semiconductor memory device according to claim 14, wherein:
the dummy program operation is performed on an erased page adjacent to the at least one programmed page.

17. The semiconductor memory device according to claim 14, wherein:
a number of pages in which the dummy program operation is performed is equal to a number of strings of the memory block.

18. The semiconductor memory device according to claim 14, wherein:
the dummy program operation is performed in a manner of programming a single-level cell (SLC).

19. The semiconductor memory device according to claim 14, wherein:
a program voltage to be used for the dummy program operation increases as a difference between the number of fail bits and the threshold number of fail bits increases.

20. A semiconductor memory device comprising:
a memory block including at least one programmed page and at least one erased page;
a control circuit configured to generate a block closed ratio indicating a ratio of a number of the at least one programmed page in the memory block to a total number of pages in the memory block; and
a peripheral circuit configured to control an operation of the memory block based on the block closed ratio.
